(19) United States
(12) Patent Application Publication
(10) Pub. No.: US 2017/0084400 A1
(43) Pub. Date: Mar. 23, 2017

(54) PRECIPITATION PROCESS FOR PRODUCING PEROVSKITE-BASED SOLAR CELLS

(71) Applicant: MONASH UNIVERSITY, Victoria (AU)

(72) Inventors: Yi-bing Cheng, Victoria (AU); Udo Bach, Victoria (US); Leone Spiccia, Victoria (US); Fuzhi Huang, Victoria (AU); Manda Xiao, Victoria (US)

(21) Appl. No.: 15/126,459

(22) PCT Filed: Mar. 17, 2015
(86) PCT No.: PCT/AU2015/050108

§ 371 Date: Sep. 15, 2016

(30) Foreign Application Priority Data
Mar. 17, 2014 (AU) 2014900910

(51) Int. Cl. H01G 9/20; C30B 7/14; C30B 7/06; H01L 51/42; C30B 29/54; C30B 28/04; H01L 51/00; C30B 7/00; C30B 19/10

(52) U.S. Cl. CPC H01G 9/2009; C30B 7/005; C30B 7/14; C30B 7/06; C30B 19/106; C30B 29/54; C30B 28/04; H01L 51/0003; H01L 51/0028; H01L 51/4226; H01G 9/2031; H01L 2031/0344

(57) ABSTRACT

A method for the preparation of a cohesive non-porous perovskite layer on a substrate (104) comprising: forming a thin film of a solution containing a perovskite material dissolved in a solvent onto the substrate to form a liquid film (104) of the solution on the substrate, applying a crystallisation agent (112) to a surface of the film to precipitate perovskite crystals from the 5 solution to form the cohesive non-porous perovskite layer (116) on the substrate.

### FIELD OF THE INVENTION

The present invention relates to techniques for producing perovskite films, which may be used in perovskite-based solar cells.

### BACKGROUND OF THE INVENTION

Harvesting energy from the sun is regarded as one of the most promising ways to solve the energy issues on the earth. Developing solar cells that can efficiently covert solar energy into electricity is therefore highly desired. Although the present dominant silicon-based photovoltaic technology can achieve power conversion efficiencies (PCEs) of ˜25%, large scale applications are still limited by the high material and manufacturing costs. Great efforts have been made to develop efficient, low-cost photovoltaic technologies, including dye-sensitized solar cells, organic photovoltaic, and colloidal nanocrystal solar cells.

Recently, perovskites (such as alkylammonium trihalolead(II)) have been demonstrated to be efficient photovoltaic materials due to their excellent light harvesting capabilities, fast carrier mobility and tolerance of defects. Perovskite nanoparticles have been used as replacement for dyes in liquid dye-sensitized solar cells and have been shown to achieve PCEs of 3.8%. Rapid development in this field has occurred in the last two years after the liquid environment was replaced with a solid hole transporting material (HTM) and the thickness of mesoporous scaffold layer was reduced from several microns, as in typical DSSCs, to a few hundred nanometers.

The PCE of perovskite-based solar cells has been improved in a number of ways, for example utilizing a mesoporous Al₂O₃ scaffold, a perovskite light absorber and an organic HTM of 2,2′,7,7′-tetrakis-(N,N-di-p-methoxyphenylamine)-9,9′-bifluorene (spiro-OMeTAD) achieved a PCE of 10%. Perovskite solar cells with PCEs of over 12% were reported by modification of the mesoporous scaffold layer and using different HTM materials. The PCEs of these organic-inorganic hybrid solar cells were further improved to 15% by controlling the loading of perovskites inside the mesoporous scaffold using a two-step sequential deposition technique. Furthermore, the perovskite sensitizer functions efficiently in a planar heterojunction system to deliver a PCE of 15%, which largely simplified the solar cell structure by eliminating the need for a mesoporous scaffold. Solution-processed planar heterojunction solar cells with a PCE of 15.7% were also reported using the two-step sequential deposition method and a thin film of ZnO nanoparticles as electron transporting material.

Thus, thin-film photovoltaics based on organic-inorganic perovskite absorbers have emerged as a promising avenue for low-cost solar technology. To date, the perovskite layer in highly efficient solar cells has generally been fabricated by either vapour deposition or a two-step sequential deposition process. The sequential deposition method requires a mesoporous scaffold to limit the growth of perovskite crystals otherwise it produces highly roughened perovskite films due to unconstrained crystal growth and uncovered pin-holes in the perovskite layer for charge recombination. High quality perovskite thin films with controlled morphology, film thickness and surface roughness are mainly achieved by vapour deposition. However, the vapour deposition process is significantly more expensive both in terms of production cost and energy consumption.

The perovskite solar cell normally has three different configurations as shown in FIG. 1: (a) a traditional mesoporous structure, which is similar to the solid-state DSC where the perovskite injects the excited electrons to mesoporous TiO₂; (b) a super mesoporous structure, in which the semiconductor TiO₂ is replaced by insulator oxide that only acts as a scaffold other than the electron conductor; and (c) a planar structure and (d) an inverted planar structure, where a p-i-n structure was formed in a layered form. Although all the configurations (a, b and c) of the methylammonium (MA) lead tri-iodide perovskite solar cell have achieved the PCE above 15%, the planar structure shows a much simpler structure and is easier for fabrication. Some OPV materials can be well applied to the planar structure, especially the inverted structure (d).

For industry purposes, a solution-based process is more feasible due to the low manufacturing cost. However, when such a method was used for the planar structure, the perovskite solar cell gave a quite low performance. For example, the CH₃NH₃PbI₃ planar solar cell only gave a PCE less than 5%.

In other configurations (such as the mesostructures), the perovskite is deposited by spin-coating. While this results in a mesoporous film that provides a device with reasonable efficiency, when this method is used for the planar structure, the resultant perovskite solar cell exhibits poor performance. For example, a CH₃NH₃PbI₃ planar solar cell formed by spin coating typically result in a PCE of less than 5%.

Very recently, a vapour-assisted two-step solution process was developed that produces high quality polycrystalline perovskite thin films. However, this process is extremely time consuming, as it takes more than 2 hours for the vapour (in this case CH₃NH₃I) to fully react with the deposited film (in this case PbI₂) to form the perovskite film.

What is desired is a faster, facile solution processing technique that can produce high quality perovskite films with controlled morphology for the construction of planar structured thin film devices with superior performance.

The present invention is directed towards addressing at least some of the aforementioned problems of the prior art.

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### SUMMARY OF THE INVENTION

The present invention relates to methods for the preparation of a perovskite layer on a substrate, and in particular, a method for forming a solar cell that includes a perovskite layer formed by the method of the invention. Specifically, the present invention relates to a fast crystallisation deposition (FCD) for the formation of the perovskite layer.

In one aspect of the invention, there is provided a method for the preparation of a cohesive non-porous perovskite layer on a substrate comprising: forming a thin film of a solution containing a perovskite material dissolved in a solvent onto the substrate to form a liquid film of the solution on the substrate, applying a crystallisation agent to a surface of the film to precipitate perovskite crystals from the solution to form the cohesive non-porous perovskite layer on the substrate.

In an embodiment, the method accelerates the precipitation of perovskite crystals in comparison to the case where perovskite is allowed to crystallise through the slow evaporation of the first solvent. Preferably, the step of applying the crystallisation agent results in the precipitation of the perovskite crystals within about 3 seconds of the application of the crystallisation agent. More preferably, within about 2 seconds. Even more preferably, within about 1 second. In the absence of the crystallisation agent, precipitation of perovskite from solution takes an extended period of time. This increased time for precipitation of perovskite from solution has a negative impact on the formation of the perovskite films and the efficiency of the solar cells prepared from them.

In an embodiment, the step of forming the perovskite layer includes forming a perovskite layer including perovskite grains that have a number average diameter of about 1 μm or less. Preferably, the grains have a number average diameter of about 800 nm or less. More preferably, the grains have a number average diameter of 600 nm or less. Most preferably, the grains have a number average diameter of 400 nm or less.

In an embodiment, the step of forming the perovskite crystals includes forming perovskite crystals in the cubic or tetragonal phase.

In an embodiment, the precipitation of perovskite crystals happens on contact between the dissolved perovskite material and the crystallisation agent. Preferably, contact between the dissolved perovskite material and the crystallisation agent results in super-saturation of the perovskite material within the solvent. This super-saturation results in the precipitation of a number of perovskite nuclei which grow to form perovskite grains in the perovskite layer.

In an embodiment the method of forming a thin film of the solution on the substrate includes coating the solution containing the perovskite material dissolved in the solvent onto the substrate to form the film of the solution on the substrate. Suitable coating techniques include roll-to-roll printing, screen printing, dip-coating, doctor blading and spin coating. Preferably the coating technique is spin coating. Spin coating is particularly advantageous as it allows the rapid formation of an evenly distributed thin film of solution over the surface of the substrate.

In an embodiment the crystallisation agent is a liquid or gas which causes the nucleation of perovskite crystals.

In certain embodiments, the crystallisation agent is a liquid in which the perovskite material is poorly soluble, very poorly soluble or insoluble. Preferably the crystallisation agent is an organic liquid. It is preferred that the organic liquid is one in which the perovskite material is poorly or very poorly soluble or insoluble, so that its addition induces precipitation of the perovskite.

Preferably, the organic liquid is selected from the group consisting of: chlorobenzene, 1,2-dichlorobenzene, 1,4-dichlorobenzene, 1,2,4-trichlorobenzene, 1,3,5-trichlorobenzene, 1,2,3-trichlorobenzene, benzene, toluene and xylene. More preferably the organic liquid is chlorobenzene. Chlorobenzene is particularly advantageous as perovskites are insoluble in chlorobenzene. When chlorobenzene comes in touch with the solvent with the perovskites dissolved therein during spin-coating, the perovskites crystallize and precipitate out rapidly and form thin films of good quality.

In an embodiment, the step of applying the crystallisation agent includes coating the crystallisation agent on to the film. Suitable coating techniques include techniques which can quickly apply this crystallisation agent to the film of the perovskite solution such as atomised vapour spraying or spin coating. Spin-coating is particularly advantageous for depositing the crystallisation agent as it allows the rapid formation of an evenly distribution of a film of this crystallisation agent over the thin film of solution containing the perovskite material.

In an alternative embodiment, the crystallisation agent is a dry gas and/or an inert gas. By dry gas it is meant a gas that is free of moisture. In this case, the step of applying the crystallisation agent to the surface of the film includes blowing the gas so that it contacts the surface of the film to evaporate the solvent from the perovskite solution, leading to faster super-saturation and crystallization of the perovskite.

In an embodiment the crystallisation agent is applied to the surface of the film from about 2 seconds to about 10 seconds after formation of the film. Preferably the crystallisation agent is applied to the surface of the film from about 2 seconds to about 8 seconds after formation of the film. More preferably, the crystallisation agent is applied to the surface of the film from about 4 seconds to about 6 seconds after formation of the film. The inventors have found that application of the crystallisation agent within this time period is conducive to forming a cohesive layer with the desired morphology, as well as providing good surface coverage of the substrate.

In the case where the film of the solution containing the perovskite material is formed via a spin coating process, the film is typically taken to have formed after any excess solution has been spun off. That is, an amount of solution is deposited onto a spin-coating apparatus for the purpose of spin coating a substrate. Excess solution is spun off the substrate as a result of the rotary motion of the substrate. The remaining solution forms a thin film over the surface of the substrate. Once this thin film has been formed, the crystallisation agent is then applied. This is preferably within the time frames discussed above.

In an embodiment, the method further includes the step of heat-treating the substrate to evaporate residual solution and crystallisation agent. This is advantageous as a heat treatment step may also assist in the promotion of nucleation of perovskite crystals. Preferably, the heat treatment step is conducted at a temperature of from about 60° C. to about 120° C. More preferably from about 80° C. to about 110° C. Most preferably the heat treatment step is conducted at about 100° C. The heat treatment step can assist in the formation of a perovskite layer having the desired morphology.

In an embodiment, the concentration of the perovskite material in the solution is from about 10 wt % to about 80 wt %. More preferably, the concentration is from about 20 wt % to about 60 wt %. The inventors have found that when the concentration of the perovskite material is in this range within the solution, films of the desired thickness can be formed. The inventors have also found that by adjusting the concentration, the thickness of the resulting film can be controlled. Therefore, the concentration of the perovskite material in solution can be used to tune the film thickness to a desired thickness.

In an embodiment, the thickness of the film layer is from about 50 nm to about 1000 nm. Preferably, the thickness of the film layer is from about 100 nm to 600 nm. More preferably, the thickness of the film layer is from about 200 nm to 500 nm. Most preferably, the thickness of the film layer is from about 300 to 400 nm.

In an alternative arrangement, it is preferred that the thickness of the film is less than 1000 nm. More preferably, the thickness of the film is less than 800 nm. Even more preferably the thickness of the film is less than 600 nm. Most preferably the thickness of the film is less than 400 nm. It is advantageous to provide a thinner film as this allows for a lighter coating which reduces material usage and cost.

In an embodiment the perovskite material is an organo-metallic compound. A wide range of materials can be used. In particular, the perovskite material is a polarizable metal ion. It is preferred that the perovskite has the general formula ABX₍ₙ₎Y₍₃₋ₙ₎, wherein A is an organic cation having a +1 oxidation state, B is a metal cation having a +2 oxidation state, X and Y are anions that are different to each other having a −1 oxidation state, and n ranges from 0 to 3 and can be a non-integer. Preferably, the organic cation is a cation that includes an amine group. More preferably, the organic cation is an alkyl amine. Preferably, the metal cation is selected from the group consisting of: Ba²⁺, zn²⁺, Ca²⁺, sr²⁺, Cd²⁺, Cu²⁺, Ni²⁺, Mn²⁺, Fe²⁺, Co²⁺, Pd²⁺, Ge²⁺, Sn²⁺, Pb²⁺, Sn²⁺, Yb²⁺, and Eu²⁺. More preferably the metal cation is selected from the group consisting of Pb²⁺or Sn²⁺. Preferably X and Y are independently selected from the group consisting of halide ions, such as fluoride (F⁻), chloride (Cl⁻), bromide (Br⁻), iodide (I⁻) and astatide (At⁻) ions. More preferably, the compound is a compound selected from: CH₃NH₃PbClₓI₃₋ₓ CH₃NH₃PbBrₓI₃₋ₓ, NH₂CH=NH₂PbClₓI₃₋ₓ and NH₂CH═NH₂PbBrₓI₃₋ₓ where x ranges from 0-3 and can be a non-integer. Most preferably the compound is CH₃NH₃PbI₃.

In an embodiment, the solvent is an organic solvent, such as an organic solvent that is able to dissolve the perovskite material at the required concentrations. Preferably, the organic solvent is selected from the group consisting of: formamides, lactones, sulfoxides, and ketones. More preferably, the organic solvent is selected from N,N-dimethylformamide (DMF), gamma-butyrolactone, dimethyl sulfoxide, or methylethyl ketone.

In another aspect of the invention, there is provided a method of forming an optoelectronic device, the device including: an anode, a substrate layer having a cohesive non-porous perovskite layer formed by the method described previously, and a cathode.

In another aspect of the invention, there is provided an optoelectronic device including: an anode, a substrate layer having a cohesive non-porous perovskite layer formed thereon, and a cathode.

Perovskite solar cells have become one of the most promising up-and-coming photovoltaic technologies. Currently, the record efficiency for a perovskite solar cell is about 15%. However, the method of the present invention is able to produce a perovskite layer on a substrate which provides a solar cell having an efficiency of about 16.2% under standard AM 1.5 conditions.

In an embodiment, the substrate is a semiconductor layer. Preferably, the semiconductor layer is an n-type semiconductor. More preferably the semiconductor layer is formed from a material selected from semi-conductive metal oxides or sulphides. Preferably, the metal oxides are selected from the group consisting of titanium, tin, zinc, gallium, niobium, tantalum, indium, neodymium, palladium, cadmium, nickel, vanadium or copper, molybdenum, or tungsten; and the metal sulfides are selected from the group consisting of sulfides of zinc or cadmium. Most preferably, the substrate is TiO₂.

In an embodiment, the anode is a transparent conducting substrate. Suitable materials include metal oxides, metal nanowires such as silver nanowire, and graphene. Preferably, the anode is a metal oxide selected from tin oxide, indium oxide, or zinc oxide.

In an embodiment the anode is doped with a dopant. Preferably the dopant is selected from the group consisting of: fluorine, tin, or aluminium. More preferably, the anode is selected from the group consisting of indium tin oxide (ITO), fluorine doped tin oxide (FTO), or aluminium doped zinc oxide (AZO). Most preferably, the anode is FTO.

In an embodiment, the cathode is carbon, a metal, or a metal oxide. Preferably, the cathode is selected from the group consisting of Ag, Au, Pt, ITO, graphene, or carbon.

In an embodiment, the device further includes a charge transporting material. Preferably the charge transporting material is a p-type or hole-transporting, semiconducting material. More preferably, the charge transporting material is a spiro compound. Preferably, the spiro compound is spiro-OMeTAD.

Alternatively the charge transporting material may be selected from polymeric hole-transporting materials such as: poly-3-hexylthiophene (P3HT), poly-[2,1,3-benzothiadiazole-4,7-diyl[4,4-bis(2-ethylhexyl)-4H-cyclopenta[2,1-b:3,4-b′]dithiophene-2,6-diyl]](PCPDTBT), (poly-[[9-(1-octylnonyl)-9H-carbazole-2,7-diyl]-2,5-thiophenediyl-2,1,3-benzothiadiazole-4,7-diyl-2,5-thiophenediyl]) (PCDTBT) and poly-triarylamine (PTAA).

Or, in another alternative, the charge transporting material may be an inorganic semiconductor hole-transporting material, such as CuI, doped CuI and CuSCN.

In another aspect of the invention, there is provided a solar cell that includes a perovskite layer formed as defined previously.

Preferably the solar cell has an efficiency that is around 10% under standard AM 1.5 conditions. More preferably, greater than 13% under standard AM 1.5 conditions. Even more preferably, the solar cell has an efficiency that is greater than 15% under standard AM 1.5 conditions. Most preferably, the solar cell has an efficiency that is greater than 16% under standard AM 1.5 conditions.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF THE DRAWINGS

FIG. 1: Schematic diagram of different structure configurations of perovskite solar cells: (a) a traditional mesoporous structure, (b) a super mesoporous structure, (c) a planar structure, and (d) an inverted planar structure.

FIG. 2: (a) SEM image of the perovskite film made by the normal method, (b) SEM image of the perovskite film made by the blowing-gas method, (c) SEM cross-section image of the perovskite solar cell made by the normal method, (d) SEM cross-section image of the perovskite solar cell made by the blowing-gas method, (e) high magnification SEM image of the perovskite film made by the blowing-gas method, and (f) high resolution TEM image of the perovskite film made by the blowing-gas method. Inset is the electron diffraction pattern of the perovskite crystals.

FIG. 3: Schematic illustration of the Fast Crystallization Deposition (FCD) process and normal spin-coating process. On top shows the normal spin-coating process for fabricating perovskite films. Shiny grey films composed of incomplete perovskite crystals were formed due to slow crystallization. Bottom shows the FCD process, a solution of chlorobenzene was introduced on top of the substrate shortly after starting the spin-coating process, which leads to fast crystallization of perovskites. Brown-colored films with full surface coverage were obtained.

FIG. 4: Morphology and structural characterization of perovskite films prepared by FCD and a normal spin-coating process. a,b, Low- and high-magnification SEM images of the surface of a perovskite film prepared by FCD. c, TEM image measured on a perovskite grain from a film produced by FCD. The (220) and (004) lattice planes are identified. d,e, Low- and high-magnification SEM images of the surface of the perovskite film prepared by normal spin-coating. f, XRD patterns of the perovskite films corresponding to (a) (blue) and (d) (red). The XRD pattern of the TiO₂ coated FTO substrate was used for comparison (black). The intensity has been normalized. The peaks corresponding to CH₃NH₃PbI₃ crystal are marked with asterisks.

FIG. 5: SEM images of the surface of the perovskite films prepared by adding chlorobenzene solution at different time. a,d, After 2 seconds; b,e, four seconds; and c,f, eight seconds.

FIG. 6: Photovoltaic device characterization. a, Schematic illustration of a typical photovoltaic device. b, Cross-sectional SEM image of an optimized device. c, J-V curve of the best-performing perovskite solar cell measured at a simulated AM1.5G solar irradiation of 100 mW cm⁻² (solid line) and in the dark (dashed line). d, IPCE spectrum of the solar cell corresponding to (c).

FIG. 7: SEM images of CH₃NH₃PbI₃ perovskite films prepared by FCD using different concentrations of perovskite solutions. (a,d) 25 wt %, (b,e) 35 wt %, (c,f) 55 wt %.

FIG. 8: UV-Visble spectra of perovskite films prepared by FCD using different concentrations of perovskite solutions in DMF.

FIG. 9: (a), (b) and (c) XRD pattern and (d), (e), (f) SEM images of the blowing-gas method prepared perovskite films sintered at different temperatures (25° C., 70° C., and 100° C.). (b) and (c) are XRD patterns with slow scan rate.

FIG. 10: (a) IV curves of the perovskite solar cells made by the blowing-gas method with different annealing temperatures (25° C., 70° C., and 100° C.), and (b) optical absorption spectra of the perovskite films annealed at 25° C. and 100° C.

FIG. 11: The I-V curve of the CuI device (non-optimised) made by the solution-based method (Voc=743 mV, Jsc=16.03 mA cm⁻², FF=0.452, PCE=5.38%)

FIG. 12: The I-V curve of the champion CuI device produced using blowing-gas method. (Voc=743 mV, Jsc=15.9 mA cm⁻², FF=0.535, PCE=6.3%)

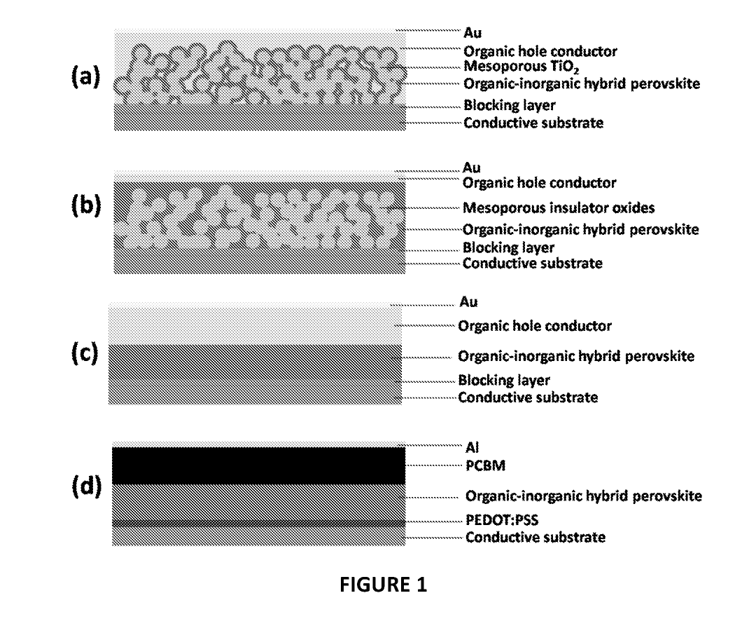

### DETAILED DESCRIPTION OF THE EMBODIMENTS

The present invention relates to a method of producing a perovskite layer on a substrate.

Typically, perovskite layers are produced by forming a perovskite solution comprising a solvent with the perovskite material dissolved therein, and applying the solution to a substrate to form a perovskite solution layer on the substrate. The solvent is then evaporated slowly via traditional drying mechanisms to form a perovskite layer. There are only a few solvents that can dissolve a high concentration of perovskite, such as N, N-dimethylformamide (DMF). These solvents generally have high boiling points (153° C. and a vapor pressure of 3.5 hPa at 20° C. for DMF). But the solvent can only be dried at relatively low temperature to prevent decomposition of organometal halide perovskites. For example the MA lead tri-iodide perovskite decomposes above 100° C. As such, the precipitation of perovskite crystals from the solution takes a relative long time due to the slow evaporation rate even at a high spin speeds in the situation where the perovskite layer is spin coated on to the substrate.

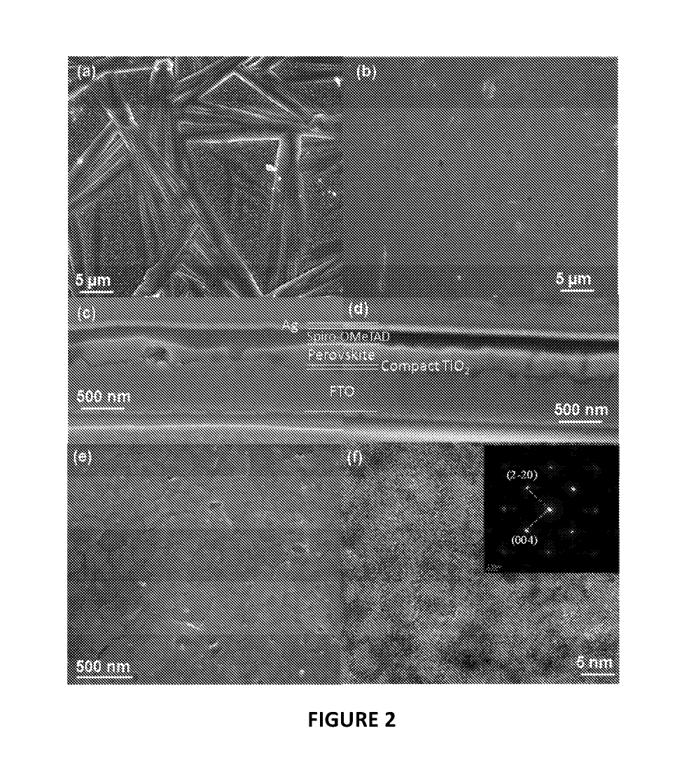

The slow precipitation of the perovskite crystals provides for slow crystal growth and allows Ostwald grain ripening to occur. The effect of this is a thin film that includes large dendritic perovskite crystals and large voids as shown in FIG. 2(a). A similar microstructure produced by the normal spin-coating method is also observed.

In a planar solar cell structure, each layer should be well covered without pin-holes; otherwise, the top layer will be in contact with the bottom layer, causing current leakage. For example, as shown in FIG. 2(a), the perovskite layer does not fully cover the n-type bottom layer (a TiO₂ compact layer). When a planar device is formed, the top p-type layer (a Spiro-OMeTAD layer) will directly contact with the TiO₂ compact layer. The electrons in the TiO₂ compact layer will recombine with the holes in the Spiro-OMeTAD layer, resulting in a poor short-circuit photocurrent (J_{sc}), open-circuit photovoltage (V_{oc}) and fill factor (FF), thus a low PCE.

The method of the present invention relates to two fast crystallisation deposition processes which can be realised by adopting either a solution based approach or a gas assisted approach. This method results in the formation of a cohesive non-porous perovskite layer.

In the solution-based approach, fast crystallisation is achieved through the application of a crystallisation solution to a layer of a perovskite solution containing a solvent within which is dissolved perovskite material. The crystallisation solution interacts with the perovskite solution to decrease the solubility of the perovskite material in the solvent, causing rapid precipitation and crystallisation of the perovskite material to form a crystallised perovskite layer.

In the gas assisted approach, fast crystallisation is achieved by applying a stream of dry gas to the layer of perovskite solution. The stream of dry and/or gas causes solvent evaporation which results in super-saturation of the perovskite material in the perovskite solution inducing fast crystallisation of the perovskite material from solution as a crystallised perovskite layer.

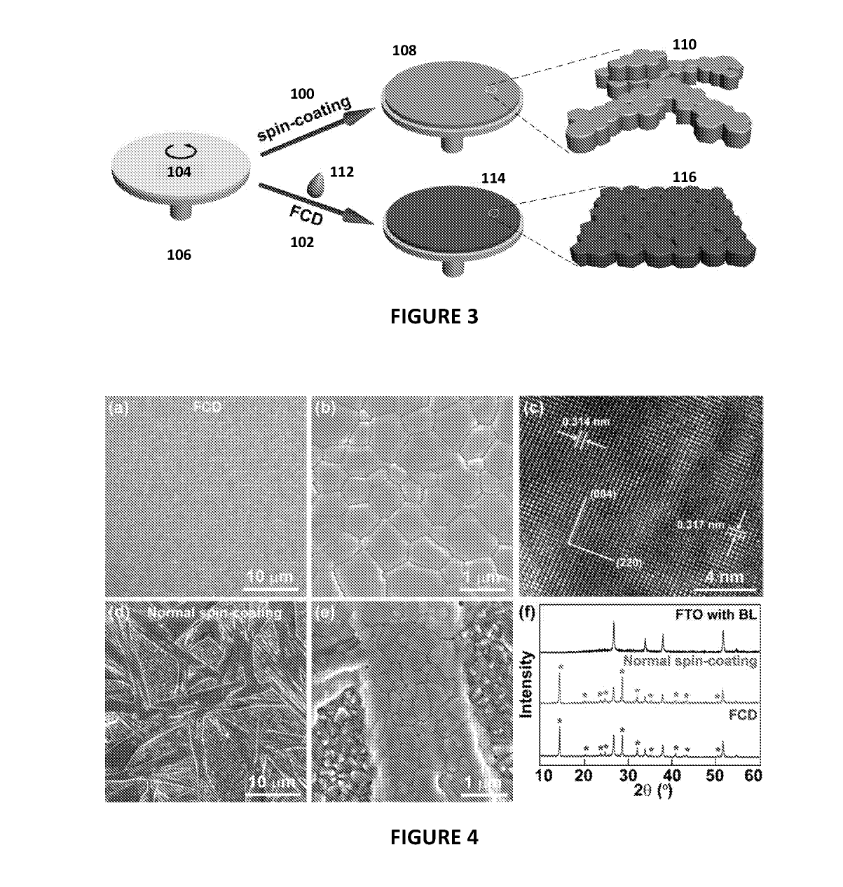

FIG. 3 provides an illustrative comparison of the perovskite film layers that result from a standard spin-coating process 100 and a fast crystallisation deposition (FCD) process 102 according to an embodiment of the invention. In both cases, a substrate 104 is loaded on to a spin coater 106. A perovskite solution containing the dissolved perovskite material is then dropped onto the surface of the substrate 104 as per as standard spin-coating process. Excess solvent is spun off, and the coating is formed.

In the standard process, the coated substrate 108 is allowed to dry by standard means known to the skilled addressee, which may include drying in an ambient environment or drying in an oven of some type. An illustration of the morphology 110 shows an uneven surface which provides incomplete coverage of the substrate.

In the FCD process, once excess solvent has spun off, a crystallisation agent 112 is applied, and is spun coat over the perovskite solution layer. The crystallisation agent induces rapid crystallisation of the perovskite material. Excess crystallisation agent is spun off, leaving a coated substrate 114. An illustration of the morphology 116 shows an evenly distributed layer which provides coverage of the substrate surface.

### Example 1

The substrates were prepared by depositing a dense TiO₂ layer (30 nm thick) on fluorine-doped tin oxide (FTO) coated glass using spray pyrolysis. A DMF solution of CH₃NH₃PbI₃ (˜45 wt %) was then spin-coated on the FTO substrate at 5000 rpm. After a short period of time (ca. 6 seconds), a solution of chlorobenzene was rapidly added and allowed to spread on the surface of the substrate. Due to the insolubility of CH₃NH₃PbI₃, and also the two components that make up this material, in chlorobenzene, rapid nucleation and growth of the perovskite crystals occurs. An instant color change of the film from light yellow to dark brown was observed. In contrast, if no chlorobenzene was introduced, the liquid film dried more slowly during spin-coating and a shiny-grey film was obtained. The films were then subjected to annealing at 100° C. for 10 min to evaporate any residual solvent and to further promote crystallization.

FIG. 4 shows the morphology and structural characterization of perovskite films prepared by FCD and a normal spin-coating process. SEM images (a) and (b) show low- and high-magnification of the surface of a perovskite film prepared by FCD. Image (c) shows a TEM image measured on a perovskite grain from a film produced by FCD. The (220) and (004) lattice planes are identified. SEM Images (d) and (e) show low- and high-magnification of the surface of the perovskite film prepared by normal spin-coating. (f) shows XRD patterns of the perovskite films corresponding to the FCD sample shown in (a) and the normal spin coating sample shown in (d). The XRD pattern of the TiO₂ coated FTO substrate was used for comparison (see FTO with BL). The intensity has been normalized. The peaks corresponding to CH₃NH₃PbI₃ crystal are marked with asterisks.

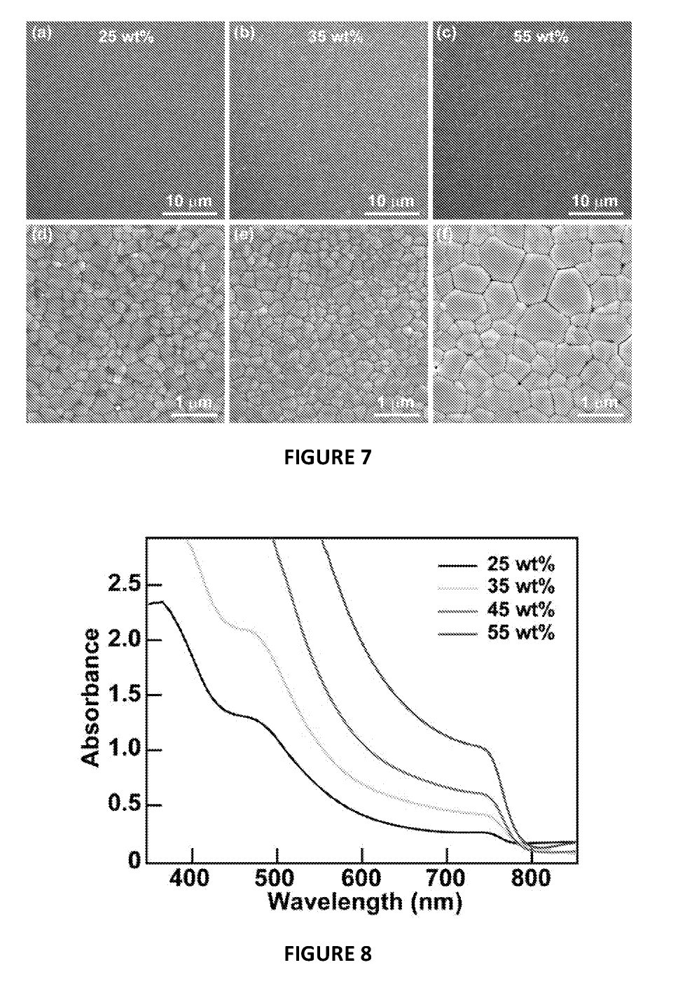

Analysis of the two films via scanning electron microscopy (SEM) revealed strikingly different morphologies. The film obtained by FCD exhibits full surface coverage of the substrate and is uniform over very large area (FIG. 4a), and is composed of grains with sizes up to microns (FIG. 4b). The transmission electron microscope (TEM) image of the CH₃NH₃PbI₃ film reveals clear lattice fringes (FIG. 4c) corresponding to those observed by X-ray diffraction (XRD) patterns (FIG. 4f), indicating the formation of a highly crystalline structure. The darker contrast observed in the TEM image is likely to result from overlapping crystallite planes. In contrast to the film obtained by FCD, the shiny-grey film obtained by normal spin-coating is comprised of larger CH₃NH₃PbI₃ crystals and there is incomplete coverage on the substrate (FIG. 4d), which is in accordance with previously reported observations. A closer examination of the large crystals reveals the presence of similar grains but with smaller sizes than those obtained by FCD (FIG. 4e), suggesting that the crystal structure is similar. This is confirmed by the nearly identical XRD patterns obtained for both films (FIG. 4f). A set of strong peaks at 14.08°, 23.48°, 28.40°, and 31.86°, assigned to (110), (211), (220), and (310) of the CH₃NH₃PbI₃ crystal, indicate that both films have CH₃NH₃PbI₃ perovskites with a tetragonal phase. A major advantage of the procedure is that the thickness of the perovskite film can be easily tuned by changing the concentration of the perovskite solutions, viz., thicknesses 150, 260, 350, and 550 nm were measured for films prepared from DMF solutions containing 25 wt %, 35 wt %, 45 wt % and 55 wt % respectively. Larger grain sizes were also found for the thicker films (see for example FIG. 7). The UV-Visible spectra indicate that, in the 350-700 nm region, 80-90% of the light passing through the FTO glass was absorbed by a perovskite film with a thickness of 350 nm and >90% for a thickness of 550 nm. Most importantly, the morphology of the uniform FCD processed CH₃NH₃PbI₃ thin films is remarkably different than that in previous reports utilizing solution-based approaches. A recent study which reported a similar film morphology on a plain substrate and a mesoporous substrate utilised a two-step vapor-assisted solution approach. However, the FCD spin-coating protocol offers a number of advantages over this approach, such as offering a single-step processing technique with shorter operation time as film formation is complete within a short time frame, such as around 1 min in this case.

### Example 2

To investigate the kinetics during film formation using FCD, chlorobenzene solution was introduced onto the spinning substrate at different time to initiate the nucleation of perovskite crystal. FIG. 3 shows SEM images of the surface of the perovskite films prepared by adding chlorobenzene solution at different times. SEM images (a) and (d) show the film after 2 seconds. SEM images (b) and (e) show the film at four seconds. SEM images (c) and (f) show the film at eight seconds.

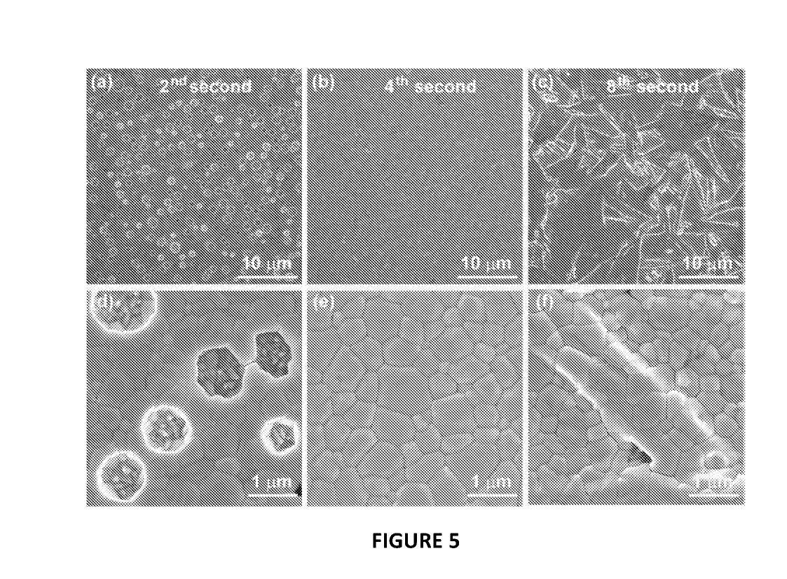

To understand the observable differences in morphology, the spin-coating process can be divided into three stages. In the first stage, the spin-off of excess solvent is a dominant process while the solution concentration remains little changed. If the chlorobenzene solution is introduced at this stage, rapid nucleation and growth of perovskite crystals happens together with solvent spin-off. Because the nucleation occurred firstly at the interface between perovskite solution and the dropped chlorobenzene solution, the mass diffusion can decrease the local concentration of perovskites near the substrate surface, leading to insufficient perovskite coverage after film formation (FIG. 5a and d). This process was observed to take approximately 3 s in this experiment. In the second stage, evaporation of the residue solvent is a major process. The substrate-perovskite interfacial interaction was enhanced due to thinning of the liquid film and the concentration of perovskite solution was increased due to evaporation. Both effects can facilitate the formation of a dense and uniform film (FIG. 5b and e). A time window between the 4th and the 6th second is found to be the most suitable for the addition of the chlorobenzene solution. In the last stage, which is later than the 8th second in this study, the liquid film started to dry and heterogeneous growth of perovskites on the substrate occurred. The addition of the chlorobenzene solution beyond this time can no longer significantly helps to achieve homogeneous growth of perovskites (FIG. 5c and f).

### Example 3

Solar cells were constructed with perovskite films produced by FCD using the optimized protocol.

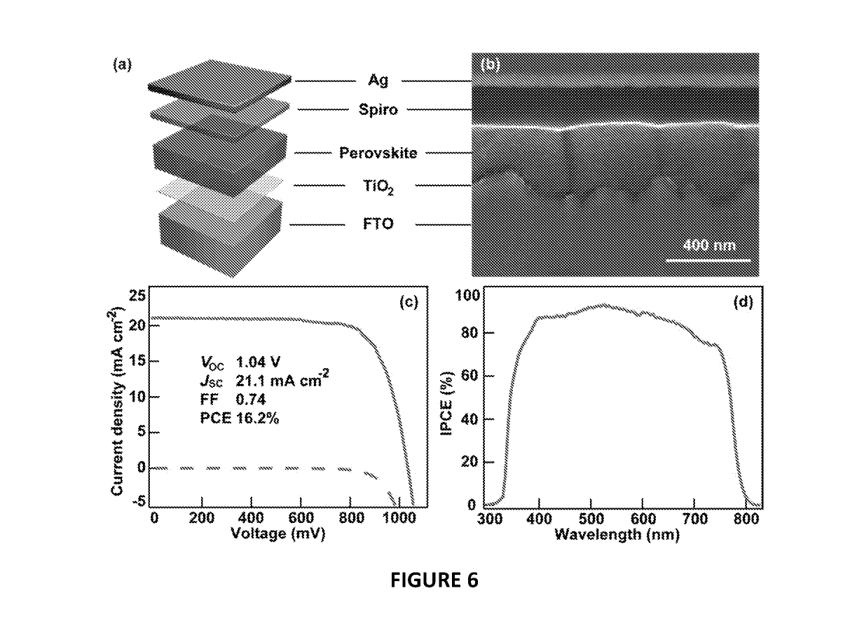

FIG. 6 illustrates photovoltaic device characterization. a, Schematic illustration of a typical photovoltaic device. b, Cross-sectional SEM image of an optimized device. c, J-V curve of the best-performing perovskite solar cell measured at a simulated AM1.5G solar irradiation of 100 mW cm⁻² (solid line) and in the dark (dashed line). d, IPCE spectrum of the solar cell corresponding to (c).

FIG. 6(a) illustrates the photovoltaic device structure. FIG. 6(b) shows a cross-sectional SEM image of an optimized photovoltaic device, taken applying focus ion beam etching. Although slight shrinkage of the spiro-OMeTAD layer was observed at the cross-section during gallium ion beam etching, which causes charging and a bright contrast at the edge of the perovskite layer, the optimized device can be clearly seen to comprise a 30-nm-thick dense TiO₂ layer on FTO, a 350 nm perovskite layer, a 180 nm spiro-OMeTAD layer, and a 70 nm thermally evaporated Ag layer as back contact. Solar cells were also fabricated using perovskite films having different thicknesses prepared by FCD and by normal spin-coating. The average photovoltaic parameters of these cells were measured under AM 1.5G illumination at an intensity of 100 mW cm⁻² and listed in Table 1.

TABLE 1
Device parameters for solar cells using perovskite films
with different thicknesses.

| Film thickness | V_{oc} | J_{sc} | FF | PCE |
|---|---|---|---|---|
| (nm) | V | mA cm⁻² | — | % |
| Normal coating | 0.52 ± 0.05 | 5.6 ± 0.9 | 0.52 ± 0.04 | 1.5 ± 0.3 |
| 150 | 0.77 ± 0.08 | 17.0 ± 0.2 | 0.61 ± 0.01 | 8.0 ± 0.02 |
| 260 | 0.96 ± 0.13 | 19.3 ± 0.3 | 0.63 ± 0.01 | 11.7 ± 0.3 |
| 350 | 0.99 ± 0.04 | 21.0 ± 0.9 | 0.67 ± 0.03 | 13.9 ± 0.7 |
| 550 | 0.97 ± 0.22 | 20.3 ± 0.2 | 0.60 ± 0.2 | 11.7 ± 0.2 |

Solar cells utilizing perovskite films prepared by normal spin-coating exhibited a PCE of only 1.5%, which mainly resulted from the low-resistance shunting and loss of light absorption due to the incomplete surface coverage. In comparison, solar cells utilizing a thin perovskite layer of 150 nm produced by FCD yield a high Jsc of 17 mA cm⁻² and a PCE of 8%, suggesting the importance of full coverage of perovskite on substrate. The increase of film thickness from 150 nm to 350 nm generally leads to higher Jsc and higher PCEs, which is mainly ascribed to the enhanced light absorption (see for example FIG. 8). Further increasing the film thickness to 550 nm resulted in a reduced Jsc and Voc. The reproducibility of results was tested for solar cells with an optimized film thickness of 350 nm by fabricating a batch of 10 devices (see Table 2). The average PCE of 13.9±0.7% is substantially larger than that achieved in previously reported studies applying two-step sequential deposition and vacuum-based vapor deposition methods. The measured electron-hole diffusion length in solution-processed CH₃NH₃PbI₃ perovskites of ˜100 nm provides a good indication of the ideal thickness for achieving an optimum Jsc for these devices. In the present experiments, however, optimized solar cells with a Jsc of 21 mA cm⁻² can be reproducibly fabricated and the value of the Jsc was observed to be proportional to perovskite film thickness in the range from 150 nm to 350 nm, which is larger than the reported electron-hole diffusion length. Furthermore, recent studies also shown that solar cells using CH₃NH₃PbI₃ thin films can achieve high J_{sc} of >20 mA cm⁻² when the film thickness is much larger than the reported diffusion length. In addition, the electron and hole diffusion lengths of formamidinium lead trihalide perovskites was determined recently to be 177 and 813 nm, respectively. The imbalance between the electron and hole diffusion length is ascribed partly to the inaccurate assumption of perfect quenching at the quencher-perovskite interface during modelling. These results together suggest that the diffusion length of electron-holes in CH₃NH₃PbI₃ is not limited to 100 nm and may vary depending on different film processing method.

FIG. 6(c) shows the current-voltage (J-V) characteristics of the best-performing cell measured in the dark and under light intensities of 100 mW cm⁻². The Jsc, Voc and fill factor, respectively, are 21.1 mA cm⁻², 1.04 V and 0.74, yielding a PCE of 16.2%. This is one of the highest reported efficiencies up to date for solution-processed organic or hybrid inorganic-organic solar cells. The incident photonto-current efficiency (IPCE) spectrum of the device shown in FIG. 6(d) shows the onset of photocurrent at 800 nm, in agreement with the band gap of the CH₃NH₃PbI₃ and with previous studies. The IPCE spectrum plateau, in the range from 400 to 600 nm has peak values of 90%. The slight drop in IPCE in the 600-800 nm region is associated with the weaker absorption of perovskite in the near IR (NIR) region (See for example FIG. 8). Integrating the product of the IPCE spectrum with the AM1.5G photon flux yields a current density of 21.5 mA cm⁻², which is in good agreement with the measured photocurrent density of 21.1 mA cm⁻². Further improvement in Jsc was anticipated if the light absorption in the NIR region could be enhanced by utilizing, for example, plasmonic technologies.

### Example 4

FTO-coated glass substrates (TEC8, Dyesol) were patterned by laser cutting and washed by ultrasonication with soap (5% Hellmanex in water), deionized water, and ethanol. A 30-nm-thick dense layer of TiO₂ was then coated on the substrates by spray pyrolytic deposition of a bis(isopropoxide)bis(acetylacetonato)titanium(IV) solution (75% in 2-propanol, Sigma-Aldrich) diluted in 2-propanol (1:9, volume ration) at 450° C. FTO glasses with dense TiO₂ layers were used within 2 weeks of their preparation.

CH₃NH₃I (0.200 g) was mixed with PbI₂ (0.578 g) in anhydrous N,N-dimethylformamide (1 mL) by shaking at room temperature for 20 min to produce a clear CH₃NH₃PbI₃ solution with concentration of 45 wt %. CH₃NH₃PbI₃ solutions with concentrations of 25, 35 and 55 wt % were prepared in similar manner. To deposit perovskite films, the CH₃NH₃PbI₃ solution (50 μL) was first dropped onto a TiO₂ coated FTO substrate (substrate area ˜1 cm×1 cm). The substrate was then spun at 5000 rpm for 30 s and after six seconds anhydrous chlorobenzene (150 μL) was quickly dropped onto the center of the substrate. This instantly changed the color of the substrate from transparent to light brown. For comparison, the effect of adding chlorobenzene after 2, 4 and 8 seconds on film crystallization was also tested. The obtained films were then dried at 100° C. for 10 min.

SEM images of CH₃NH₃PbI₃ perovskite films prepared by FCD using different concentrations of perovskite solutions. (a,d) 25 wt %, (b,e) 35 wt %, (c,f) 55 wt % are shown in FIG. 7.

UV-Visble spectra of perovskite films prepared by FCD using different concentrations of perovskite solutions in DMF are shown in FIG. 8.

The hole-transporting material was deposited by spin coating at 2200 rpm for 30 s. The spin coating solution was prepared by dissolving 52.8 mg (2,2′,7,7′-tetrakis(N,N-di-p-methoxyphenylamine)-9,9-spirobifluorene) (spiro-MeOTAD), 10 μL of a stock solution of 500 mg mL-1 lithium bis(trifluoromethylsulphonyl)imide in acetonitrile and 14.4 μL 4-tert-butylpyridine in 640 μL chlorobenzene. Device fabrication was finally completed by thermal evaporation of a 70-nm-thick film of silver as the cathode. Devices were left in a desiccator overnight and tested in next day. Note that the champion cell was made using spiro-MeOTAD from Luminescence Technology Corp., while other cells were made using spiro-MeOTAD from Merck KGaA. All the device fabrication process was done in the N₂-filled glove box.

A sun simulator (Oriel) fitted with a filtered 1,000 W xenon lamp was used to provide simulated solar irradiation (AM1.5, 100 mW cm⁻²). Current-voltage characteristics were measured using a Keithley 2400 source meter. The output of the light source was adjusted using a calibrated silicon photodiode (Peccell Technologies). The photodiode was fitted with a color filter provided by the supplier to minimize the optical mismatch between the calibration diode and the solar cells. The solar cells were masked with a non-reflective metal aperture of 0.16 cm² to define the active area of the device and avoid light scattering through the edges. IPCE spectra were recorded using a 150 W xenon lamp (Oriel) fitted with a monochromator (Cornerstone 260) as a monochromatic light source. The illumination spot size was chosen to be slightly smaller than the active area of the test cells. IPCE photocurrents were recorded under short-circuit conditions using a Keithley 2400 source meter. The monochromatic photon flux was quantified by means of a calibrated silicon photodiode (Peccell Technologies). The surface morphology of perovskite films was investigated using an FEI Nova NanoSEM 450 microscope operating at 5 kV. The cross section images were performed with a FEI Nova dual beam, focussed ion beam system, combined SEM and gallium ion beam instrument. Prior to performing the cross section, two Pt protecting layers were deposited in situ with an electron beam source at 6.3 nA and ion beam source at 0.30 nA. The milling of the cross sections was obtained with a gallium ion source at a 52° tilting angle. The absorption spectra of the perovskite films were measured on a PerkinElmer Lambda 950 UV/VIS/NIR spectrometer. X-ray diffraction (XRD) experiments were conducted by a Philips X-ray diffractometer with Cu Kα radiation. The samples were scanned from 10° to 60° with a step-size of 0.02°.

TABLE 2
Photovoltaic parameters of a batch of ten devices measured
under 100 mW cm⁻² simulated AM1.5G illumination.

| Cell | V_{oc} | J_{sc} | FF | PCE |
|---|---|---|---|---|
| — | V | mA cm⁻² | — | % |
| 1 | 0.98 | 21.5 | 0.69 | 14.4 |
| 2 | 0.98 | 21.6 | 0.69 | 14.6 |
| 3 | 0.99 | 20.6 | 0.68 | 13.9 |
| 4 | 0.99 | 21.1 | 0.71 | 14.8 |
| 5 | 0.99 | 20.4 | 0.67 | 13.6 |
| 6 | 0.97 | 21.7 | 0.68 | 14.3 |
| 7 | 0.99 | 21.4 | 0.61 | 12.9 |
| 8 | 0.99 | 21.3 | 0.68 | 14.4 |
| 9 | 0.98 | 21.4 | 0.66 | 13.8 |
| 10 | 0.99 | 21.6 | 0.66 | 14.2 |
| Average | 0.98 ± 0.01 | 21.3 ± 0.4 | 0.67 ± 0.03 | 14.1 ± 0.5 |

### Example 5

A perovskite layer was formed on a substrate by spreading 25 μL 45 wt % CH₃NH₃PbI₃ DMF solution on to a TiO₂ compacted layer coated FTO substrate on a spin-coater. A 60 psi dry gas stream was blown to the film during the spun at 6500 rpm for 10 second from the third second of the spin-coating. The films then annealed at different temperatures on a hotplate for 5 min, and then cooled down to room temperature on a steel substrate. Finally, Spiro-OMeTAD and a metal conductor were deposited in sequence.

Here a simple accelerated precipitation method based on a dry gas blowing method was applied during the spin-coating process and achieved a much higher solar cell performance of PCE of 13.9%, as shown in Table 3. All the photovoltaic parameters were improved, especially the photocurrent which was doubled and the efficiency tripled. During the spin-coating, the dry gas blowing technique accelerated the drying process of the solvent, and induced a rapid precipitation of the perovskite crystals. FIG. 2b shows an SEM image of a perovskite film prepared by the blowing-gas method. Compared to the normal spin-coating method (FIG. 2a), the new method can prepare a perovskite film with a near full coverage of the bottom layer. The cross-sections of the two devices were also compared, as shown in FIG. 2c and d. The perovskite layer prepared by the normal spin-coating method is not even and the film thickness varied greatly, while the perovskite film made by the blowing-gas method is coated by the single perovskite grains in thickness and therefore very homogenous, giving a flat surface. The uneven layer of the perovskite layer also caused an uneven coating of the top Spiro-OMeTAD layer. The blowing-gas method produced a uniform film consisted of ˜300 nm grains compactly covering on the substrate, as shown in FIG. 2e. From FIGS. 2c and 2e, it can be concluded that the perovskite film prepared by the blowing-gas method consisted of single perovskite grains, approximately 300 nm in both the lateral size and film thickness. A high resolution TEM image (FIG. 2f) of the perovskite film made by the blowing-gas method showed the fine crystal lattice fringes of a single perovskite grain, indicating it is a single crystal. The electron diffraction pattern (FIG. 2f inset) confirmed the grain to be a single tetragonal crystal. A film consisted of single perovskite crystals would be beneficial for fast charge transport. From the electron diffraction pattern in the inset of FIG. 2f, it was found that the (110) plane of the perovskite crystal was aligned in parallel with the substrate surface. The preferential orientation of the perovskite crystals would facilitate the charge transport in the device.

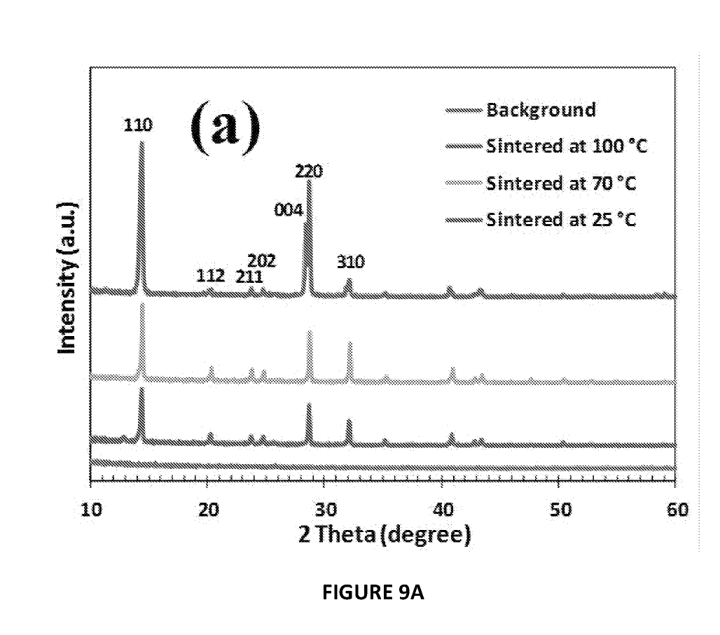

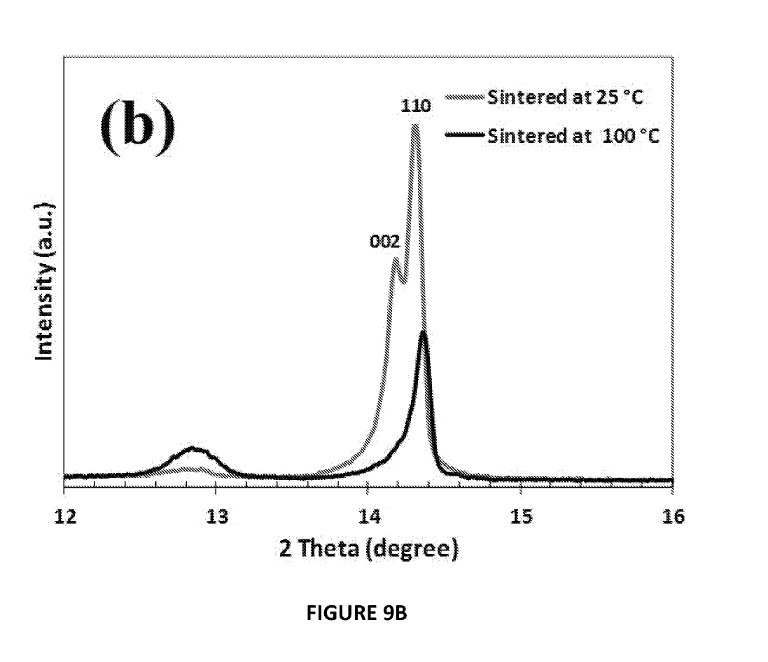

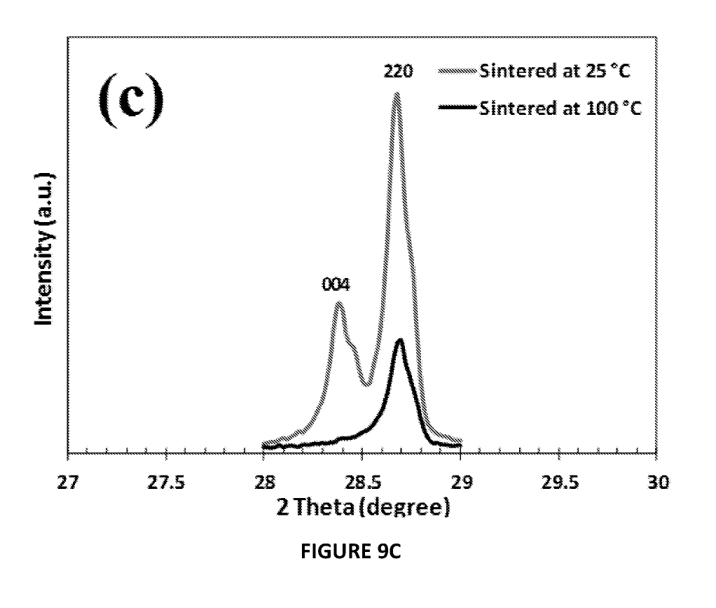

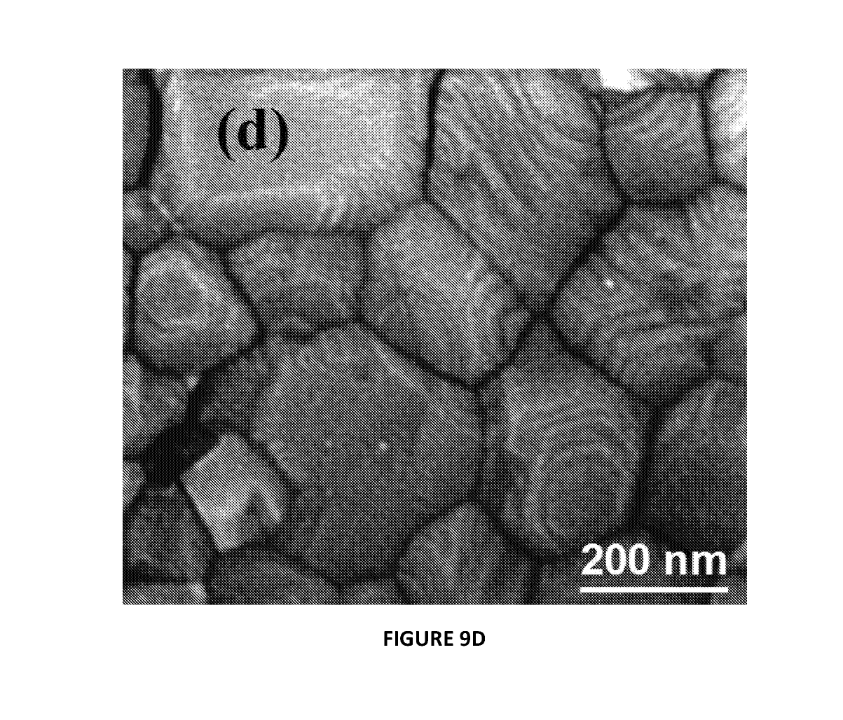

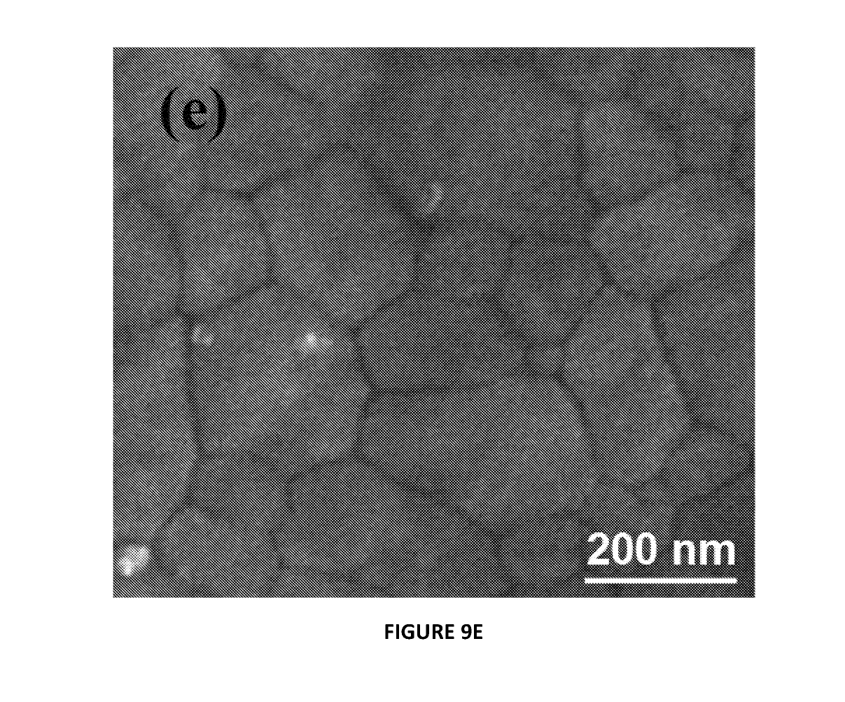

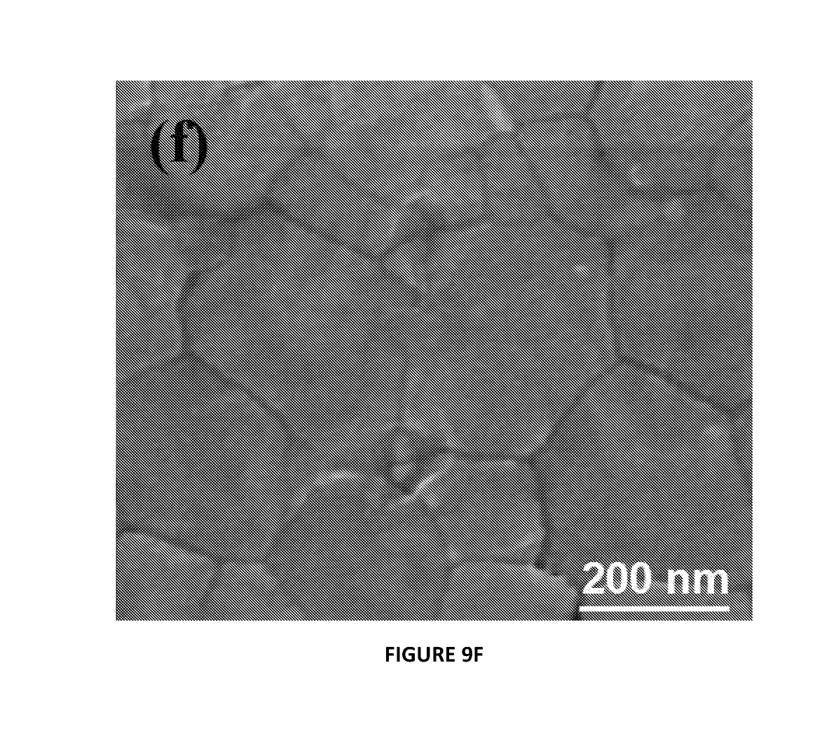

After the perovskite was deposited by the blowing-gas method, a low temperature annealing process (˜100° C.) was required to achieve a high performance solar cell. A detailed study was carried out to investigate the effect of the annealing process. Different annealing temperatures (25° C., 70° C. and 100° C.) were applied after the perovskite films were formed. FIG. 9 shows the XRD patterns of the films annealed at different temperatures. It was found that the perovskite films were mainly consisted of tetragonal phase and the annealing temperatures did not change the crystalline phase. The crystals showed a pattern of very sharp diffraction peaks, indicating relatively good crystallinity. There is a main difference, however, that the film annealed at 25° C. showed a clear splitting in diffraction peaks of (002), (110) (FIGS. 9b) and (004), (220) (FIG. 9c) respectively. This is clear evidence of a tetragonal symmetry. After annealing at 100° C., however, both the peak positions showed only one peak with the d-spacings corresponding to the (110) and (220) planes of the tetragonal phase respectively (FIG. 9c, d). But the crystalline phase after the annealing at 100° C. still maintained to be tetragonal, confirmed by the existence of both (211) and (213) peaks which are inconsistent with the cubic phase. This may indicate that the crystallography orientations of the grains in the films are different after annealed at different temperatures. FIG. 9d, e, and f showed the SEM images of the films annealed at different temperatures. Compared to the higher temperature annealed films, the 25° C. annealed one had a rougher surface and some sub-band structures were shown in the grains. When the temperature increased, the sub-structure became less obvious at 70° C. and completely disappeared at 100° C. The phase transformation from tetragonal to cubic MA lead iodide perovskite takes place at 60° C. and it is a reversible phase transformation. Combining the XRD and SEM results, it could be assumed that a microstructural refinement occurred with the phase transformation during the annealing process and the crystals are better orientated during the higher temperature treatment.

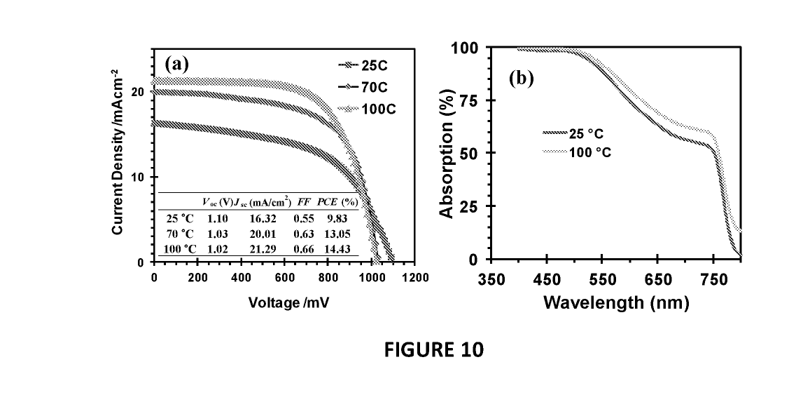

The performance of the perovskite films annealed at different temperatures was evaluated when made into devices. FIG. 10a shows the IV curves for the solar cells annealed at different temperatures. All the devices showed a quite similar photovoltage, but a higher annealing temperature resulted in a higher photocurrent. The 100° C. sintered devices gave the highest photocurrent of above 21 mA/cm². The higher annealing temperature would induce a better crystallinity and then yield a better light harvesting ability as shown in FIG. 4b. The fill factor also followed the same trend. A high orientation of the crystals induced by the higher annealing temperature would reduce the series resistance due to the enhanced charge transport through the perovskite crystals. The decreased series resistance is reflected on the tails of the IV curves (FIG. 10a). A higher slope indicated a lower resistance. The fill factor is governed by the shunt and series resistance. Thus a low resistance of the film annealed at a high temperature achieved a higher fill factor. All together the 100° C. sintered devices showed the highest PCE of 14.4%, which is close to the reported value (15.4%) made by the more complicated vapor deposition method.

Performance results for a device fabricated using a normal spin-coating method are shown in Table 3. As can be seen, the device exhibits poor photovoltaic performance in comparison with a method according to an embodiment of the invention.

TABLE 3
Performance results for a device fabricated according to
prior art methods using a spin coating procedure as
compared with a gas assisted method according to an
embodiment of the invention.

| | V_{oc} (mV) | J_{sc} (mA/cm²) | FF | PCE (%) |
|---|---|---|---|---|
| Normal method | 811 ± 62 | 10.5 ± 1.4 | 0.56 ± 0.2 | 4.6 ± 1.1 |
| Blowing-gas method | 1000 ± 22 | 20.9 ± 0.4 | 0.67 ± 0.1 | 13.9 ± 0.4 |

### Example 6

Deposition of CuI on perovskite films, for example for devices made by using CuI as a hole conductor for the layer structured perovskite based solar cells.

30.4 mg of CuI was dissolved in 1.6 ml of a mixture of 1:39 propyl sulphide and chlorobenzene. A few microliters of this solution was taken to the tip of a glass pasture pipette and 2-3 drops were placed on the section of the FTO glass that was not coated by the perovskite film. Next the drop was spread over the perovskite film maintaining a constant distance between the film and the pipette. The spreading was done at a rate of ˜0.2 cm s⁻¹. A full solution bead was maintained between the pipette and the film to form a uniform CuI film. The perovskite film was kept at 850° C. throughout CuI coating and extra 2-3 minutes were required to evaporate the propyl sulphide. The optimum film thickness was achieved with 22 repeats of the CuI spreading. However, comparable results were also observed from the films with 18 to 40 CuI solution spreading repeats.

Three drops of 10% w/w dispersion of graphite in chlorobenzene was placed and spread over CuI film using glass pipette. Then it was heated on the hot plate at 80° C. for 1 minute.

A copper tape was pasted on the graphite film. The positive and negative contacts were soldered to copper plate and FTO glass respectively.

The thickness of a 16-time spread CuI film was around 340 nm.

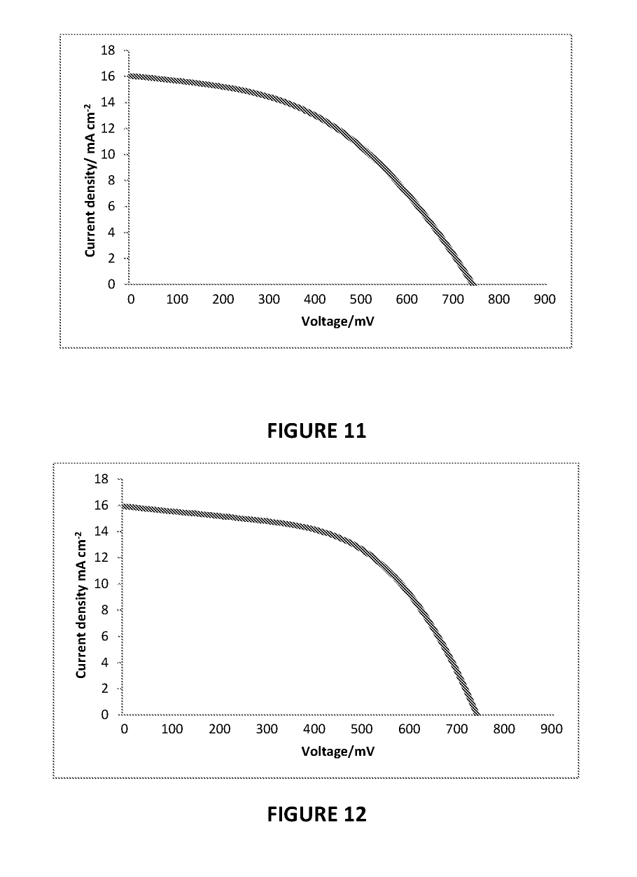

The reduced overall thickness of the device support to avoid the energy loss of excited charges. This is further exemplifies by the improved Voc of the device by 30% than previous devices, see FIG. 11. The optimum devices made by both methods show an open circuit voltage of ˜740 mV (see FIGS. 11 and 12).

According to the results of two batches that have been produced using the two novel deposition methods employing a thin layer of CuI have shown a higher reproducibility (Table 4 and 5). The average efficiency of the two batches shows a significant improvement (Table 4 and 5) over results in previously published literature. The cell area of the devices kept constant at 1 cm² and the active area was set at 0.16 cm² by placing a mask on it.

TABLE 4
I-V data of 8-device batch made by the gas-assisted method.

| Cell | V_{oc} | J_{sc} | FF | Efficiency |
|---|---|---|---|---|
| — | V | mA cm⁻² | — | % |
| 1 | 699 | 15.64 | 0.476 | 5.21 |
| 2 | 628 | 16.21 | 0.503 | 5.12 |
| 3 | 656 | 14.76 | 0.463 | 4.48 |
| 4 | 680 | 17.04 | 0.494 | 5.72 |
| 5 | 756 | 16.23 | 0.503 | 6.17 |
| 6 | 677 | 17.25 | 0.485 | 5.66 |
| 7 | 663 | 15.93 | 0.474 | 5.01 |
| 8 | 688 | 16.15 | 0.497 | 5.52 |
| Average | 680 ± 37 | 16.2 ± 0.8 | 0.49 ± 0.02 | 5.4 ± 0.5 |

TABLE 5
I-V data of 8-device batch made by the solution-
assisted method.

| Cell | V_{oc} | J_{sc} | FF | Efficiency |
|---|---|---|---|---|
| — | V | mA cm⁻² | — | % |
| 1 | 716 | 16.88 | 0.414 | 5.00 |
| 2 | 682 | 16.57 | 0.439 | 4.96 |
| 3 | 700 | 15.95 | 0.392 | 4.38 |
| 4 | 650 | 17.56 | 0.466 | 5.32 |
| 5 | 641 | 16.35 | 0.484 | 5.07 |
| 6 | 720 | 15.85 | 0.465 | 5.31 |
| 7 | 656 | 16.49 | 0.405 | 4.39 |
| 8 | 743 | 16.03 | 0.452 | 5.38 |
| Average | 688 ± 37 | 16.5 ± 0.6 | 0.44 ± 0.05 | 5.0 ± 0.4 |

It will be understood that the invention disclosed and defined in this specification extends to all alternative combinations of two or more of the individual features mentioned or evident from the text or drawings. All of these different combinations constitute various alternative aspects of the invention.

1. A method for the preparation of a cohesive non-porous perovskite layer on a substrate comprising:
forming a thin film of a solution containing a perovskite material dissolved in a solvent onto the substrate to form a liquid film of the solution on the substrate,
applying a crystallisation agent to a surface of the film to precipitate perovskite crystals from the solution to form the cohesive non-porous perovskite layer on the substrate.

2. The method of claim 1, wherein the method of forming a thin film of the solution on the substrate includes spin-coating the solution containing the perovskite material dissolved in the solvent onto the substrate to form the film of the solution on the substrate.

3. The method of claim 1, wherein the crystallisation agent is an organic liquid.

4. The method of claim 3, wherein the organic liquid is selected from the group consisting of: chlorobenzene, 1,2-dichlorobenzene, 1,4-dichlorobenzene, 1,2,4-trichlorobenzene, 1,3,5-trichlorobenzene, 1,2,3-trichlorobenzene, benzene, toluene and xylene.

5. The method of claim 1, wherein the step of applying the crystallisation agent includes spin coating the crystallisation agent on to a surface of the thin film.

6. The method of claim 1, further including the step of heat treating the substrate to evaporate residual solvents present in film.

7. The method of claim 1, wherein the crystallisation agent is a dry gas, and the step of applying the crystallisation agent to the surface of the film includes blowing the crystallisation agent over the surface of the film.

8. The method of claim 1, wherein the crystallisation agent is applied to the surface of the film from about 2 seconds to about 10 seconds after formation of the film.

9. (canceled)

10. The method of claim 1, wherein the concentration of the perovskite material in the solution is from about 10 wt % to about 80 wt %.

11. The method of claim 1, wherein the thickness of the film layer is from about 50 nm to about 800 nm.

12. (canceled)

13. The method of claim 1, wherein the perovskite material is an compound having the general formula ABX₍ₙ₎Y₍₃₋ₙ₎, wherein A is an organic cation having a +1 charge, B is a metal cation having a +2 oxidation state, X and Y are anions that are different to each other having a −1 oxidation state, and n is 0, 1, 2, or 3.

14. The method of claim 13, wherein the organic cation is an alkyl amine.

15. The method of claim 13, wherein the metal cation is selected from the group consisting of: Ba²⁺, Zn²⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Sn²⁺, Yb²⁺, and Eu²⁺.

16. The method of claim 13, wherein X and Y are independently selected from the group consisting of halide ions, such as fluoride (F⁻), chloride (Cl⁻), bromide (Br⁻), iodide (I⁻) and astatide (At⁻) ions.

17. The method of claim 13, wherein the compound is CH₃NH₃PbI₃.

18. The method of claim 1, wherein the solvent is an organic solvent selected from the group consisting of: formamides, lactones, sulfoxides, and ketones.

19. A method of forming an optoelectronic device, the device including:
providing an anode and a cathode,
providing a substrate layer between the anode and the cathode, the substrate layer having a perovskite layer formed thereon by the method of claim 1.

20. The method of claim 19, wherein, the substrate is a semiconductor layer formed from a material selected from semi-conductive metal oxides or sulphides, the oxides selected from the group consisting of titanium, tin, zinc, gallium, niobium, tantalum, indium, neodymium, palladium, cadmium, nickel, vanadium or copper, molybdenum, or tungsten; and the metal sulfides selected from the group consisting of sulfides of zinc or cadmium.

21. (canceled)

22. The method of claim 1, wherein the step of forming the perovskite layer includes forming a perovskite layer including perovskite grains that have a number average diameter of about 1 μm or less.

23. (canceled)

24. The method of claim 1, wherein the step of forming the perovskite crystals includes forming perovskite crystals in the cubic or tetragonal phase.

25. (canceled)

26. (canceled)

27. (canceled)
